(19) United States
(12) Patent Application Publication
(10) Pub. No.: US 2024/0022045 A1
(43) Pub. Date: Jan. 18, 2024

(54) MESA/TRENCH FREE VERTICAL CAVITY SURFACE EMITTING LASER (VCSEL)

(71) Applicant: Mellanox Technologies, Ltd., Yokneam (IL)

(72) Inventors: Petter Westbergh, Gothenburg (SE); Attila Fulop, Gothenburg (SE)

(21) Appl. No.: 17/812,796

(22) Filed: Jul. 15, 2022

(51) Int. Cl. H01S 5/183; H01S 5/125

(52) U.S. Cl. CPC H01S 5/18377; H01S 5/125

(57) ABSTRACT

A vertical-cavity surface-emitting laser (VCSEL) is provided that includes a first reflector; a second reflector; and an active region disposed between the first reflector and the second reflector. The first reflector defines a first reflector characteristic dimension in a plane that is substantially perpendicular to an emission axis of the VCSEL, and the second reflector defines a second reflector characteristic dimension in a plane that is substantially perpendicular to the emission axis. The first reflector characteristic dimension is substantially equal to the second reflector characteristic dimension, which enables the VCSEL to exhibit improved heat dissipation compared to conventional VCSELs.

### TECHNICAL FIELD

Various embodiments relate to VCSELs and/or fabrication of VCSELs that are free of the geometry restrictions of a mesa or trench-defined VCSEL. Various embodiments relate to VCSELs and/or the fabrication of VCSELs that have improved thermal impedance. Various embodiments relate to VCSELs and/or the fabrication of VCSELs that have lengths, widths, and/or diameters that are greater than 30 microns or greater than 40 microns (e.g., 100 microns or larger).

### BACKGROUND

Various VCSELs include components configured to provide lateral electrical and/or optical confinement. For example, one or more layers of the VCSEL are oxidized inward from about a perimeter of the VCSEL to form an oxidized layer that may be used to provide lateral electrical and/or optical confinement. This results in the device geometry in a standard oxide-confined VCSEL to be constrained by the requirements provided by limited oxidation distances.

### BRIEF SUMMARY

Various embodiments provide VCSELs, or other similar semiconductor devices, and/or methods for fabricating such VCSELs, or similar semiconductor devices, that are not defined by a mesa or trenches. Various embodiments provide VCSELs, or other similar semiconductor devices, and/or methods for fabricating such VCSELs, or similar semiconductor devices, with decreased thermal impedance compared to conventional VCSELs. Various embodiments provide VCSELs and/or methods for fabricating VCSELs, for example, where the electrical and optical apertures are defined in a manner that does not require trenches or a mesa to prevent electrical and/or optical leakage. In various embodiments, the VCSELs have characteristic dimensions in a plane that is substantially perpendicular to an emission axis of the VCSEL that are greater than 30 microns or greater than 40 microns (e.g., 300 microns, in an example embodiment). In various embodiments, the VCSELs have a thermal impedance that is substantially defined by the material properties of at least one of the first reflector, active region or second reflector of the VCSEL. For example, in various embodiments, the VCSELs have a thermal impedance that is less than 1800 K/W for an optical aperture of 6 microns.

According to an aspect of the present disclosure, a vertical-cavity surface-emitting laser (VCSEL) is provided. In an example embodiment, the VCSEL comprises a first reflector; a second reflector; and an active region disposed between the first reflector and the second reflector. The first reflector, the active region, and the second reflector are aligned with one another along an emission axis of the VCSEL. The first reflector defines a first reflector characteristic dimension in a plane that is substantially perpendicular to the emission axis and the second reflector defines a second reflector characteristic dimension in a plane that is substantially perpendicular to the emission axis. The first reflector characteristic dimension is substantially equal to the second reflector characteristic dimension.

In an example embodiment, the active region defines an active region characteristic dimension in a plane that is substantially perpendicular to the emission axis and the active region characteristic dimension is substantially equal to the first reflector characteristic dimension and to the second reflector characteristic dimension.

In an example embodiment, the second reflector characteristic dimension is at least one of greater than 30 microns or greater than 40 microns.

In an example embodiment, a surface of the second reflector that is opposite the active region along the emission axis is substantially planar across the second reflector characteristic dimension.

In an example embodiment, a thermal impedance of the VCSEL is less than 1800 K/W for an optical aperture of 6 microns.

In an example embodiment, the second reflector comprises an ion implantation region and an etched feature.

In an example embodiment, the second reflector is a distributed Bragg reflector comprising alternating layers of higher and lower Al-content AlGaAs, and the ion implantation region is substantially formed in a lower Al-content AlGaAs layer of the distributed Bragg reflector.

In an example embodiment, the ion implantation region is disposed 100 nm to 500 nm from the active region.

In an example embodiment, the ion implantation region is lithographically defined.

In an example embodiment, the etched feature has a height of 5 to 70 nm in a direction substantially parallel to the emission axis.

In an example embodiment, the ion implantation region defines an electrical aperture of the VCSEL.

In an example embodiment, the etched feature defines an optical aperture of the VCSEL.

In an example embodiment, the VCSEL further comprises a via, a first contact, and a first contact pad, the via and the first contact configured to place the first contact pad in electrical communication with a first surface of the active region.

In an example embodiment, the VCSEL further comprises a second contact and a second contact pad, wherein the second contact at least partially defines an emission aperture of the VCSEL, the second contact in electrical communication with the second contact pad.

In an example embodiment, a thermal impedance of the VCSEL is substantially defined by material properties of at least one of the first reflector, active region, or second reflector.

According to another aspect of the present disclosure, a method for fabricating a VCSEL with improved heat dissipation is provided. In an example embodiment, the method comprises fabricating a first reflector, active region, and a first portion of a second reflector; forming an ion implantation region in the first portion of the second reflector, the ion implantation region defining an electrical aperture; etching an etched feature in the first portion of the second reflector, the etched feature defining an optical aperture; and forming a second portion of the second reflector. The first reflector defines a first reflector characteristic dimension in a plane that is substantially perpendicular to an emission axis of the VCSEL, and the second reflector defines a second reflector characteristic dimension in a plane that is substantially perpendicular to the emission axis. The first reflector characteristic dimension is substantially equal to the second reflector characteristic dimension.

In an example embodiment, the first reflector, active region, and first portion of the second reflector are formed by one or more epitaxial growth processes and the second portion of the second reflector is formed by an epitaxial regrowth process.

In an example embodiment, wherein the ion implantation region is formed by applying a mask that defines the electrical aperture and dosing the first portion of the second reflector with ions with an ion energy that causes the ions to be implanted in the ion implantation region at a distance of 100 nm to 500 nm from the active region.

In an example embodiment, the method further comprises forming one or more vias and depositing one or more contacts onto the VCSEL.

In an example embodiment, the etched feature has a height in a range of 5 nm to 70 nm.

### BRIEF DESCRIPTION OF THE DRAWING(S)

Having thus described the invention in general terms, reference will now be made to the accompanying drawings, which are not necessarily drawn to scale, and wherein:

FIG. 1 illustrates a schematic cross-sectional view of a vertical-cavity surface-emitting laser (VCSEL) taken in a plane substantially parallel to the emission axis of the VCSEL, in accordance with an example embodiment;

FIG. 2 illustrates a top view of the VCSEL shown in FIG. 1, in accordance with an example embodiment;

FIG. 3 illustrates a top view of an example array of VCSELs, in accordance with an example embodiment; and

FIG. 4 provides a flowchart illustrating various processes, procedures, and/or operations for fabricating a VCSEL, such as that shown in FIG. 1, for example, in accordance with an example embodiment.

### DETAILED DESCRIPTION OF THE INVENTION

The present invention now will be described more fully hereinafter with reference to the accompanying drawings, in which some, but not all embodiments of the inventions are shown. Indeed, these inventions may be embodied in many different forms and should not be construed as limited to the embodiments set forth herein; rather, these embodiments are provided so that this disclosure will satisfy applicable legal requirements. Like numbers refer to like elements throughout. As used herein, terms such as “top,” “bottom,” “front,” etc. are used for explanatory purposes in the examples provided below to describe the relative position of certain components or portions of components. Accordingly, as an example, the term “top current spreading layer” may be used to describe a current spreading layer; however, the current spreading layer may be on the top or on the bottom, depending on the orientation of the particular item being described. As used herein, the terms “generally,” “approximately,” and “substantially” refer to tolerances within appropriate manufacturing and/or engineering standards and/or within user measurement capabilities.

Various embodiments provide VCSELs, or other similar semiconductor devices, and/or methods for fabricating such VCSELs, or similar semiconductor devices, that are not defined by a mesa or trenches. Various embodiments provide VCSELs, or other similar semiconductor devices, and/or methods for fabricating such VCSELs, or similar semiconductor devices, with decreased thermal impedance compared to conventional VCSELs. Various embodiments provide VCSELs and/or methods for fabricating VCSELs, for example, where the electrical and optical apertures are defined in a manner that does not require trenches or a mesa to prevent electrical and/or optical leakage. In various embodiments, the VCSELs have characteristic dimensions in a plane that is substantially perpendicular to an emission axis of the VCSEL that are greater than 30 microns or greater than 40 microns (e.g., 300 microns, in an example embodiment). In various embodiments, the VCSELs have a thermal impedance that is substantially defined by the material properties of at least one of the first reflector, active region, or second reflector of the VCSEL. For example, in various embodiments, the VCSELs have a thermal impedance that is less than 1800 K/W.

Lateral electrical and/or optical confinement within VCSELs is used to control the electric field within the active region of the VCSEL such that the active region will generate sufficient optical power for lasing activity. In various VCSELs, a variety of methods have been used to provide appropriate lateral electrical and/or optical confinement, such as use of a buried tunnel junction, oxide confinement, and ion implantation regions (see, for example, U.S. patent application Ser. No. 17/249,224, filed Feb. 24, 2021, the content of which is hereby incorporated by reference in its entirety). Similar lateral electrical and/or optical confinement is required within various other semiconductor devices.

As noted above, in conventional VCSELs, one or more layers of the VCSEL are oxidized inward from about a perimeter of the VCSEL mesa to provide appropriate lateral electrical and/or optical confinement for the intended application of the VCSEL. In other words, one or more layers of the VCSEL are oxidized from an outer edge of the layer in toward a middle portion of the layer. However, such an oxidization process is limited by a finite distance into the VCSEL that can be oxidized. Thus, oxide-confined VCSELs are required to have a mesa of a limited size. However, semiconductor materials tend to be poor radiators of heat. Thus, the finite size of the mesa of the VCSEL causes the VCSEL to have very high thermal impedance. For example, conventional oxide-confined VCSELs have a maximum diameter of approximately 25 microns, resulting in a thermal impedance of approximately 2000 K/W for a 6 micron optical aperture. Such a high thermal impedance can lead to excess heating of the VCSEL due to the difficulty in transporting thermal energy away from the VCSEL mesa structure. Such excess heating may reduce the operational quality and/or reliability of the VCSEL in various circumstances. Thus, technical problems exist relating to thermal dissipation in conventional VCSELs.

Embodiments of the present invention provide technical solutions to these technical problems. In particular, various embodiments provide semiconductor devices, such as VCSELs, and/or methods for fabricating semiconductor devices where a mesa or trenches are not required to define electrical and/or optical confinement and/or to electrically and/or optically isolate an individual semiconductor device. Therefore, characteristic dimensions of the semiconductor device, for example, in a plane that is transverse to and/or substantially perpendicular to the emission axis (in the example of a VCSEL) that are larger than 25 microns. For example, the characteristic dimensions of the semiconductor device, for example, in a plane that is transverse to and/or substantially perpendicular to the emission axis (in the example of a VCSEL) are 30 microns or more, in an example embodiment, and 40 microns or more, in an example embodiment. In another example embodiment, the characteristic dimensions of the semiconductor device are 100 microns or more. Thus, the material properties of the first reflector, active region, and/or second reflector, in the example of a VCSEL, substantially define the thermal impedance of the semiconductor device (e.g., VCSEL). This results in lower thermal impedance than similar conventional semiconductor devices.

As should be understood, thermal impedance is a measure of how much resistance there is to the flow of heat through a material. Thus, the lower the thermal impedance of the semiconductor device, the more effectively and efficiently heat can be dissipated away from a heat source of the device. For example, for a VCSEL, the lower the thermal impedance of the VCSEL, the more effectively and efficiently heat can be dissipated away from the light generating portion of the VCSEL (e.g., of the active region). Thus, a VCSEL with lower thermal impedance is less likely to experience excess heating and subsequent over-heating-related failures, degradation in performance, and/or the like. Various embodiments of the present disclosure therefore provide improvements to the field of semiconductor devices, such as VCSELs.

### An Example VCSEL

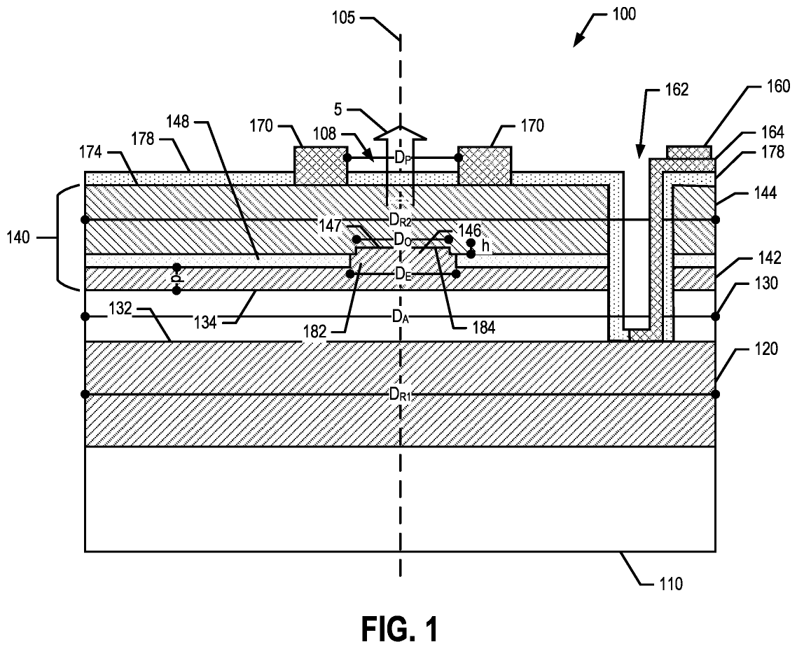

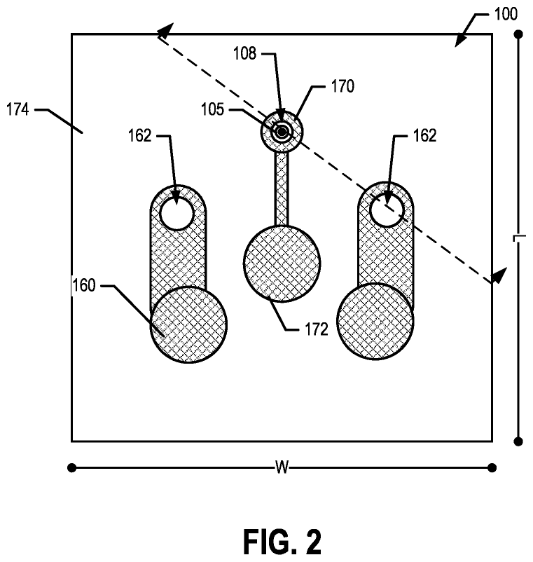

FIG. 1 illustrates a cross-section of an example embodiment of a vertical-cavity surface-emitting laser (VCSEL) 100 where the cross-section is taken in a plane comprising the emission axis 105 (e.g., in a plane substantially parallel to the emission axis 105). FIG. 2 illustrates a top view of the VCSEL 100. The dashed line in FIG. 2 corresponds to the cross-sectional view of FIG. 1.

The VCSEL is defined by characteristic dimensions in a plane substantially perpendicular to the emission axis 105. For example, in FIG. 2, the characteristics dimensions of the length L and the width W of the VCSEL are illustrated. In various embodiments, a characteristic dimension of the VCSEL (e.g., the length L and/or width W) is greater than 30 microns. In various embodiments, a characteristic dimension of the VCSEL (e.g., the length L and/or width W) is greater than 40 microns. In various embodiments, a characteristic dimension of the VCSEL (e.g., the length L and/or width W) is in a range of 30-1000 microns (e.g., 300-400 microns).

Due to the characteristic dimension of the VCSEL 100 being larger than conventional VCSELs (e.g., the length L and/or width W of the VCSEL 100 being 30 microns or larger), the thermal impedance of the VCSEL 100 is substantially defined by the (bulk) material properties of the VCSEL 100. For example, the (bulk) material properties of the first reflector 120, active region 130, and/or second reflector 140 substantially define the thermal impedance of the VCSEL 100. In various embodiments, the thermal impedance of the VCSEL 100 is 1800 K/W or less. In various embodiments, thermal impedance of the VCSEL 100 is 1500 K/W or less (e.g., 1400 K/W or less).

In various embodiments, the VCSEL 100 is formed on a substrate 110. In various embodiments, the substrate 110 is a wafer or a portion thereof. In various embodiments, the substrate 110 is and/or comprises GaAs, InP, Si, and/or another material appropriate for the application.

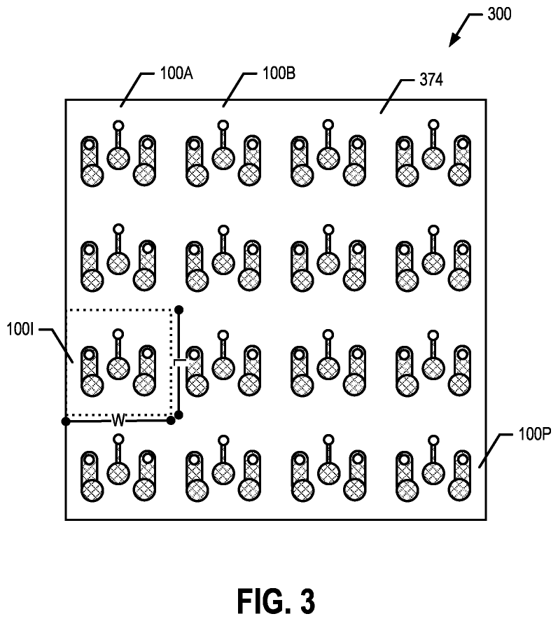

In various scenarios, a plurality of VCSELs 100 may be generated on a large substrate 110 (e.g., a wafer) so as to form a VCSEL array 300 (see FIG. 3). In an example embodiment, the substrate (e.g., wafer) has at least one dimension (e.g., length, width, or radius) larger than two inches. Once fabrication of one or more VCSELs and/or other electro and/or optical devices are fabricated on the substrate, the substrate (e.g., wafer) may be diced into multiple chips. For example, the VCSELs 100 and/or electro-optical systems formed on the substrate (e.g., wafer) may be separated via a dicing procedure, used as an array of VCSELs, incorporated into an integrated VCSEL system, and/or the like, as appropriate for the application.

The structure of the VCSEL 100 includes an active material structure disposed between two reflectors. For example, FIG. 1 illustrates the active region 130 disposed between a first reflector 120 and a second reflector 140. For example, a first surface 132 of the active region is formed and/or disposed on the first reflector 120, and a second reflector 140 is formed and/or disposed on a second surface 134 of the active region 130.

In various embodiments, the active region 130 is configured to be operable to generate light of a characteristic wavelength. In various embodiments, the first and second reflectors 120, 140 form a cavity therebetween configured to cause the light generated by active region 130 to be emitted as a laser beam and/or laser pulses.

For example, the VCSEL 100 may emit light 5 through the second reflector 140 or through the first reflector 120, as appropriate for the application. For example, in an example embodiment, the VCSEL 100 is configured to emit light through the first reflector 120 and the substrate 110. In another embodiment, the VCSEL 100 is configured to emit light 5 through the second reflector 140 (e.g., via the physical emission aperture 108), as shown in FIG. 1.

As can be seen in FIG. 1, the direction in which light 5 is emitted from the VCSEL 100 defines an emission axis 105 of the VCSEL. In an example embodiment, the VCSEL 100 is generally rotationally and/or radially symmetric about the emission axis 105. In various embodiments, the emission direction can be configured towards first reflector 120 (e.g., in a bottom emitting configuration).

In various embodiments, the first reflector 120 and/or the second reflector 140 comprise reflector stacks (e.g., dielectric layer stacks). For example, the first reflector 120 and/or the second reflector 140 may comprise un-doped semiconductor distributed Bragg reflector (DBR) mirrors. For example, the first reflector 120 and/or the second reflector 140 may comprise un-doped alternating layers of higher and lower Al-content aluminum gallium arsenide (AlGaAs). For example, the higher Al-content AlGaAs layers have a higher Al-content than the lower Al-content AlGaAs layers. For example, the first reflector 120 and/or the second reflector 140 comprise un-doped alternating layers of AlₓGa₁₋ₓAs and Al_{y}Ga_{1-y}As with 0≤x<y≤1, in an example embodiment.

In an example embodiment, the first reflector comprises doped DBR mirrors that are doped with a first type of dopant (e.g., n-type dopant), and the second reflector 140 comprises doped DBR mirrors that are doped with a second type of dopant (e.g., p-type dopant).

In various embodiments, the second reflector 140 may comprise a DBR mirror, and the first reflector 120 may comprise a micro-electromechanical systems (MEMS) component. For example, a MEMS component may be fabricated on the substrate 110 to form the first reflector 120. In an example embodiment, the first reflector 120 comprises a MEMS high-contrast grating (HCG). In various embodiments, the first reflector 120 may be a hybrid reflector comprising a combination of MEMS components and reflector stacks, such as DBR mirrors.

In various embodiments, a MEMS HCG comprises a thin element having a grating pattern thereon/therein with the period of the grating pattern being smaller than the characteristic wavelength of the corresponding VCSEL 100. In such embodiments, the grating pattern is formed in a first material and is surrounded by and/or embedded in a second material, where the second material has a lower index of refraction than the first material. In various embodiments in which the first reflector 120 comprises a MEMS component (e.g., a MEMS HCG), the MEMS component may be fabricated with lateral coupling functionality such that it is possible to directly couple the light 5 emitted by the VCSEL 100 in one lateral direction or in both lateral directions. In various embodiments, a lateral direction is a direction that is substantially parallel to a plane defined by a surface of the substrate 110. For example, the MEMS component of the first reflector 120 (e.g., MEMS HCG and/or the like) may be used to optically couple the VCSEL to another optical and/or electro-optical component formed on and/or mounted to the substrate 110.

In various embodiments, the second reflector 140 comprises means for defining an optical aperture 184 and means for defining an electrical aperture 182. For the illustrated embodiment of the VCSEL 100, the means for defining an electrical aperture 182 is ion implantation region 148. In various embodiments, the ion implantation region 148 is formed by implanting ions within a layer of the DBR of the second reflector 140.

In various embodiments, the ions implanted into the layer of the DBR of the second reflector 140 are heavy ions, meaning ions that are heavier than hydrogen ions. For example, in various embodiments, the ions implanted into the layer of the DBR of the second reflector 140 comprise and/or consist of oxygen ions, silicon ions, germanium ions, helium ions, and/or the like and/or combinations thereof. In various embodiments, the layer of the DBR of the second reflector 140 into which the ions are implanted is a lower aluminum content AlGaAs layer.

In various embodiments, the ion implantation region is disposed a distance d from the second surface 134 of the active region 130. In various embodiments, the distance d is in a range of 100 nm to 500 nm. For example, in various embodiments, the ion implantation region is disposed 100 nm to 500 nm from the active region 130. In an example embodiment, the ion implantation region is disposed, at least in part, within 100 nm of the active region 130. In an example embodiment, the ion implantation region 148 and/or the electrical aperture 182 formed by the ion implantation region 148 is lithographically defined to have a desired shape and/or size.

In various embodiments, the ion implantation region 148 defines the electrical aperture 182. In various embodiments, the electrical aperture defines an electrical aperture diameter D_{E}. In various embodiments, the electrical aperture diameter D_{E}, measured in a plane that is substantially perpendicular to the emission axis 105, is in a range of 2 microns to 20 microns. In various embodiments, the ion implantation region 148 is non-conductive and therefore causes the flow of electrical current that is flowing through the VCSEL 100 through the electrical aperture 182.

In various embodiments, the second reflector 140 further comprises means for defining the optical aperture 184. In various embodiments, the optical aperture 184 is defined by etched features 146. In various embodiments, the etched feature has a height h in a range of 5 nm to 70 nm in a direction substantially parallel to the emission axis 105. For example, the second reflector 140 may be partially formed (e.g., on a second surface 134 of the active region 130). For example, some of the DBR layers of the second reflector 140 are formed (e.g., epitaxially grown). An etching process is then performed to form the etched feature 146. In an example embodiment, a lithographical etching process is performed to form the etched feature 146.

In various embodiments, the etched feature 146 defines the optical aperture 184. In various embodiments, the optical aperture defines an optical aperture diameter D_{O}. In various embodiments, the optical aperture diameter D_{O}, measured in a plane that is substantially perpendicular to the emission axis 105, is in a range of 2 microns to 10 microns. In various embodiments, the optical aperture diameter is less than the electrical aperture diameter (e.g., D_{O}<D_{E}). In an example embodiment the optical aperture diameter is approximately equal to or larger than the electrical aperture diameter.

In various embodiments, the shape of the etched feature 146 (e.g., in a plane that is substantially perpendicular to the emission axis 105) defines and/or is configured to filter the optical mode(s) of the VCSEL 100 that are emitted by the VCSEL 100. For example, the optical mode(s) of the VCSEL are confined within the optical aperture 184. In various embodiments, a shape of the etched feature 146 (and therefore the shape of the optical aperture 184) defines an optical beam profile and/or polarization of light 5 emitted by the VCSEL 100 through the optical aperture 184. For example, various embodiments enable the fabrication of an array of VCSELs where each VCSEL of the array emits light of a different polarization (e.g., by forming etched features 146 of different shapes in each VSEL of the array), enabling polarization-division multiplexing (PDM).

In various embodiments, the second surface 174 of the second reflector 140 is substantially planar. For example, the second surface 174 of the second reflector 140 defines a plane that is substantially perpendicular to the emission axis 105. In various embodiments, the second surface 174 defines the characteristic dimension of the VCSEL 100. For example, the second surface 174 of the second reflector 140 may have a length L and/or a width W that is greater than 30 microns (e.g., 300 microns).

In various embodiments, the first reflector 120 defines a first reflector characteristic dimension, such as diameter D_{R1}. In various embodiments, the active region 130 defines an active region characteristic dimension, such as diameter D_{A}. In various embodiments, the second reflector 140 defines a second reflector characteristic dimension, such as diameter D_{R2}. The characteristic dimensions of the first reflector 120, active region 130, and second reflector 140 are approximately the same (e.g., D_{R1}=D_{A}=D_{R2}). As the VCSEL 100 does not include an etched mesa, the second reflector 140 and the active region 130, are not etched to a smaller characteristic dimension than the first reflector 120. This enables the bulk material of the first reflector 120, active region 130, and second reflector 140 to assist in dissipating heat away from the light generating portion of the active region 130, in various embodiments. This increased dissipation of heat (increased with respect to VCSELs that include mesas or trenches that cause the active region and/or second reflector to be significantly smaller in size than the VCSEL 100) enables the VCSEL 100 to operate in a more reliable manner at a broader range of operating voltages. For example, the VCSEL 100 may be driven with a larger current (compared to a conventional VCSEL) while still dissipating heat efficiently enough to prevent excess heating of the VCSEL. For example, the maximum current with which a conventional data communications application VCSEL is operated is approximately 9 mA. In various embodiments, the VCSEL 100 may be operated with a current above 10 mA (e.g., 12-13 mA).

The active region 130 is disposed between the first and second reflectors 120, 140. In various embodiments, the active region 130 comprises a stack of quantum well and/or quantum dot layers. In an example embodiment, the active region 130 comprises one or more active layers comprising an InGaAs-based material, a GaAs-based material, or other material configured to generate light of the characteristic wavelength of the VCSEL 100.

In various examples, the active region 130 comprises a plurality of quantum wells where light 5 is generated between the first and second reflectors 120 and 140. In some examples, the active region 130 comprises multi-quantum well and/or dots layers (MQLs) of VCSEL gain media. For example, the MQLs may comprise a stack or a series of quantum wells disposed between a series of (quantum) barriers. In various embodiments, the MQLs are configured to generate light of that is similar in wavelength to the characteristic wavelength of the VCSEL 100. In various embodiments, the MQLs are configured to generate light having a wavelength in the 700-2000 nm wavelength range. In various embodiments, the MQLs are formed from GaAs or InGaAs-based semiconductor materials.

In various embodiments, the VCSEL 100 may comprise various other layers that are not shown in FIG. 1. For example, in an example embodiment, a first current spreading layer is disposed between the first reflector 120 and the active region 130 (or between the first reflector 120 and the substrate 110), and/or a second current spreading layer is disposed between the active region 130 and the second reflector 140 (or on the second surface 174 of the second reflector). For example, the first and second current spreading layers may act as global contacts providing voltage and/or current to the active region 130. In an example embodiment, the first and/or second current spreading layer may comprise a contact layer. In various embodiments, the contact layer may be a thin metal layer (e.g., a thin metal ring) configured to distribute current across a corresponding one of the first and/or second current spreading layer. For example, the contact layer may distribute current across the second current spreading layer with less resistance than when the current is distributed across the second current spreading layer by the second current spreading layer alone. In various embodiments, the first and second current spreading layers are configured (possibly with corresponding contact layer(s)) to provide electrical bias (e.g., a voltage differential and/or a current) to surfaces of the active region 130 that are substantially perpendicular to the emission axis 105. For example, the first and second current spreading layers may be configured (possibly with corresponding contact layer(s)) to establish a voltage differential and/or provide a current between the first surface 132 of the active region 130 and the second surface 134 of the active region 130.

In an example embodiment, the VCSEL 100 further comprises a cap layer and/or insulating layer formed on the second surface 174 of the second reflector 140.

In various embodiments, the VCSEL 100 comprises electrical contacts. For example, the VCSEL 100 comprises a first contact 160. The first contact 160 is in electrical communication with the first surface 132 of the active region 130 through via 162. For example, conductive material 164 extends from the second surface 174 of the second reflector 140 through the via 162 to cause the first surface 132 of the active region 130 to be in electrical communication with the first contact 160. In an example embodiment, the first contact 160 is and/or comprises a first contact pad disposed on or insulating layer 178 formed on the second surface 174 of the first reflector 140.

In various embodiments, the VCSEL 100 further comprises a second contact 170. In an example embodiment, the second contact 170 is in electrical communication with the second surface 134 of the active region 130 (e.g., via the second reflector 140). For example, in an example embodiment, the second contact 170 is in electrical communication with the second surface 174 of the second reflector 140 such that a bias may be applied between the first surface 132 of the active region 130 and the second surface 134 of the active region 130 to cause the active region 130 to form light 5. In an example embodiment, the second contact 170 comprises and/or is in electrical communication with second contact pad 172. In an example embodiment, the second contact pad is disposed on the second surface 174 of the first reflector 140 (and/or on a cap layer or insulating layer formed on the second surface 174 of the first reflector 140).

In various embodiments, the second contact 170 and/or a portion thereof forms at least a portion of circle that defines the physical emission aperture 108 of the VCSEL 100. The physical emission aperture 108 defines an emission aperture diameter D_{P}. In various embodiments, the emission aperture diameter is approximately the same size or larger than the optical aperture diameter (e.g., D_{P}≥D_{O}). In an example embodiment, the emission aperture diameter is smaller than the optical aperture. In various embodiments, the optical aperture diameter D_{O}, measured in a plane that is substantially perpendicular to the emission axis 105, is in a range of 2 microns to 10 microns.

In various embodiments, the VSELs 100 may be fabricated as and/or formed into a VCSEL array 300, as shown in FIG. 3. For example, a plurality of VCSELs 100 (e.g., 100A, 100B, . . . , 1001, . . . , 100P) may be fabricated as and/or formed into a VCSEL array 300. The VCSEL array 300 may have a generally planar surface 374 (e.g., other than vias 162 and first and second contacts 160, 170 and/or contact pads). In other words, the VCSELs 100 do not form individual mesas such that the surface 374 of the VCSEL array 300 may be generally planar.

### Example Method of Fabricating an Example VCSEL

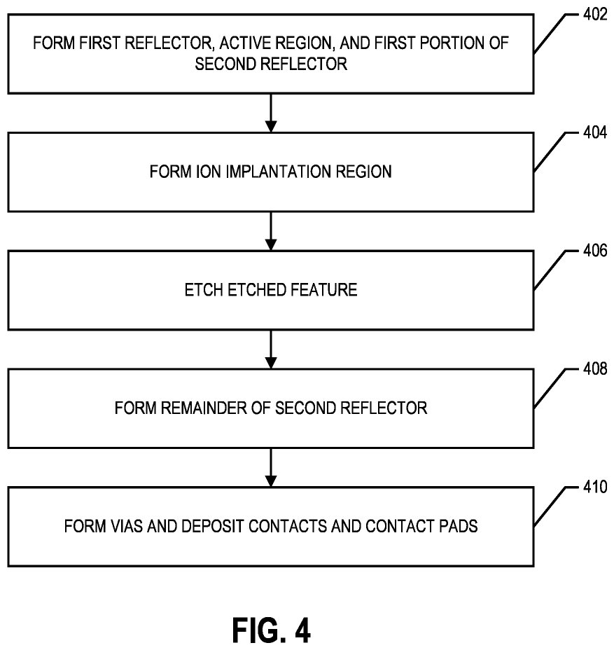

FIG. 4 provides a flowchart illustrating various processes, procedures, operations, and/or the like for fabricating a VCSEL 100. Starting at step/operation 402, the first reflector 120, active region 130, and the first portion 142 of the second reflector 140 are formed on a substrate 110. For example, the first reflector 120, active region 130, and the first portion 142 of the second reflector 140 may be formed using one or more epitaxial growth processes, bonding processes (see U.S. application Ser. No. 17/249,224, filed Feb. 24, 2021, the content of which is hereby incorporated by reference in its entirety), and/or the like. In an example embodiment, the first portion 142 of the second reflector 140 terminates in a layer of the alternating higher and lower Al-content AlGaAs layers of the DBR of the second reflector 140.

At step/operation 404, the ion implantation region 148 is formed. For example, a masking process (e.g., photographic masking, lithographical masking) is used to define an ion implantation region 148 and the electrical aperture 182, in an example embodiment. For example, a mask may be used to prevent the implantation of ions in the electrical aperture 182. For example, an area defined using a mask or other technique (e.g., a lithographic technique and/or the like) may be dosed with desired ions (e.g., oxygen ions, silicon ions, germanium ions, helium ions, and/or the like and/or combinations thereof) of an appropriate ion energy so as to form the ion implantation region 148. In various embodiments, the ion energy is configured such that the ion implantation region is disposed and/or location a distance d from the second surface 134 of the active region 130. In various embodiments, the distance d is in the range of 100 nm to 500 nm. In an example embodiment, the ion implantation region is disposed, at least in part, within 100 nm of the active region 130. In various embodiments, the ion energy is configured such that the ion implantation process does not cause damage within the active region 130. In various embodiments, the ion implantation region is formed within a GaAs layer of the DBR of the second reflector 140.

At step/operation 406, the etched feature 146 is formed. In various embodiments, the etched feature 146 is performed by performing an etching process. The etching process may be a dry etch, wet etch, deep reactive ion etching (DRIE), a masked etching process, a lithographic etching process, and/or the like. In various embodiments, the etched feature 146 is etched to have a height h in a range of 5 nm to 25 nm. In various embodiments the etched feature 146 is etched to have a shape that is the desired optical aperture 184 shape so as to control the optical mode and/or polarization of light 5 emitted by the VCSEL 100.

At step/operation 408, additional processing is performed to complete the fabrication of the second reflector 140. For example, the second portion 144 of the second reflector 140 may be formed and/or fabricated via an epitaxial regrowth process. For example, the DBR layers of the second portion 144 of the second reflector 140 may be grown and/or fabricated onto the first portion 142 of the second reflector 140 to complete the fabrication of the second reflector 140. In an example embodiment, a cap layer or insulating layer may be formed and/or deposited on the second surface 174 of the second reflector 140. In an example embodiment, a portion of a cap layer and/or insulating deposited onto the physical emission aperture 108 is removed (e.g., via etching).

At step/operation 410, one or more vias 162 may be formed (e.g., etched) into the VCSEL 100 and the first and second contacts 160, 170 and corresponding contact pads may be deposited and patterned. For example, the via 162 may be etched into the VCSEL, the conductive material 164 may be deposited into the via 162 and/or onto the surface of the VCSEL 100 and the first and second contacts 160, 170 and corresponding contact pads may be deposited onto the surface of the VCSEL.

Notably, fabricating the VCSEL 100 does not comprise an etching step to define a mesa of the VCSEL or to etch trenches to define the VCSEL. Rather, the characteristic dimensions (e.g., length L and/or width W) of the VCSEL 100 are larger than 30 microns, and, in some embodiments, larger than 40 microns. This enables improved dissipation of heat away from the light generating portions of the active region 130. The VCSEL 100 may therefore be reliably operated at higher biases, compared to conventional VCSELs. As such, the VCSEL 100 provides improved performance and technical advantages over conventional VCSELs.

Many modifications and other embodiments of the inventions set forth herein will come to mind to one skilled in the art to which these inventions pertain having the benefit of the teachings presented in the foregoing descriptions and the associated drawings. Therefore, it is to be understood that the inventions are not to be limited to the specific embodiments disclosed and that modifications and other embodiments are intended to be included within the scope of the appended claims. Although specific terms are employed herein, they are used in a generic and descriptive sense only and not for purposes of limitation.

That which is claimed:

1. A vertical-cavity surface-emitting laser (VCSEL) comprising:
a first reflector;
a second reflector; and
an active region disposed between the first reflector and the second reflector,
wherein the first reflector, the active region, and the second reflector are aligned with one another along an emission axis of the VCSEL,
wherein the first reflector defines a first reflector characteristic dimension in a plane that is substantially perpendicular to the emission axis and the second reflector defines a second reflector characteristic dimension in a plane that is substantially perpendicular to the emission axis, and
wherein the first reflector characteristic dimension is substantially equal to the second reflector characteristic dimension.

2. The VCSEL of claim 1, wherein the active region defines an active region characteristic dimension in a plane that is substantially perpendicular to the emission axis and the active region characteristic dimension is substantially equal to the first reflector characteristic dimension and to the second reflector characteristic dimension.

3. The VCSEL of claim 1, wherein the second reflector characteristic dimension is at least one of greater than 30 microns or greater than 40 microns.

4. The VCSEL of claim 1, wherein a surface of the second reflector that is opposite the active region along the emission axis is substantially planar across the second reflector characteristic dimension.

5. The VCSEL of claim 1, wherein a thermal impedance of the VCSEL is less than 1800 K/W.

6. The VCSEL of claim 1, wherein the second reflector comprises an ion implantation region and an etched feature.

7. The VCSEL of claim 6, wherein the second reflector is a distributed Bragg reflector comprising alternating layers of higher and lower Al-content AlGaAs, and the ion implantation region is substantially formed in a GaAs layer of the distributed Bragg reflector.

8. The VCSEL of claim 6, wherein the ion implantation region is disposed within 500 nm of the active region.

9. The VCSEL of claim 6, wherein the ion implantation region is lithographically defined.

10. The VCSEL of claim 6, wherein the etched feature has a height of 5 to 70 nm in a direction substantially parallel to the emission axis.

11. The VCSEL of claim 6, wherein the ion implantation region defines an electrical aperture of the VCSEL.

12. The VCSEL of claim 6, wherein the etched feature defines an optical aperture of the VCSEL.

13. The VCSEL of claim 1, further comprising a via, a first contact, and a first contact pad, the via and the first contact configured to place the first contact pad in electrical communication with a first surface of the active region.

14. The VCSEL of claim 1, further comprising a second contact and a second contact pad, wherein the second contact at least partially defines an emission aperture of the VCSEL, the second contact in electrical communication with the second contact pad.

15. The VCSEL of claim 1, wherein a thermal impedance of the VCSEL is substantially defined by material properties of at least one of the first reflector, active region, or second reflector.

16. A method for fabricating a VCSEL, the method comprising:
fabricating a first reflector, active region, and a first portion of a second reflector;
forming an ion implantation region in the first portion of the second reflector, the ion implantation region defining an electrical aperture;
etching an etched feature in the first portion of the second reflector, the etched feature defining an optical aperture; and
forming a second portion of the second reflector,
wherein the first reflector defines a first reflector characteristic dimension in a plane that is substantially perpendicular to an emission axis of the VCSEL, and the second reflector defines a second reflector characteristic dimension in a plane that is substantially perpendicular to the emission axis, and
wherein the first reflector characteristic dimension is substantially equal to the second reflector characteristic dimension.

17. The method of claim 16, wherein the first reflector, active region, and first portion of the second reflector are formed by one or more epitaxial growth processes and the second portion of the second reflector is formed by an epitaxial regrowth process.

18. The method of claim 16, wherein the ion implantation region is formed by applying a mask that defines the electrical aperture and dosing the first portion of the second reflector with ions with an ion energy that causes the ions to be implanted in the ion implantation region within 500 nm of the active region.

19. The method of claim 16, further comprising forming one or more vias and depositing one or more contacts onto the VCSEL.

20. The method of claim 16, wherein the etched feature has a height in a range of 5 nm to 70 nm.
